(19) United States
(12) Patent Application Publication
(10) Pub. No.: US 2007/0287221 A1
(43) Pub. Date: Dec. 13, 2007

(54) Fabrication process for crystalline zinc oxide semiconductor layer

(75) Inventors: Beng S. Ong, Mississauga (CA); Yuning Li, Mississauga (CA); Yiliang Wu, Mississauga (CA)

Correspondence Address: PATENT DOCUMENTATION CENTER, XEROX CORPORATION, 100 CLINTON AVE., SOUTH, XEROX SQUARE, 20TH FLOOR, ROCHESTER, NY, 14644, US

(73) Assignee: Xerox Corporation

(21) Appl. No.: 11/450,998

(22) Filed: Jun. 12, 2006

(51) Int. Cl. H01L 21/16; H01L 21/00

(52) U.S. Cl. 438/104

(57) ABSTRACT

A process for fabricating at least one semiconductor layer of a thin film transistor composed of: liquid depositing one or more zinc oxide-precursor compositions and forming the at least one semiconductor layer of the thin film transistor including crystalline zinc oxide preferentially oriented with the c-axis perpendicular to the plane of the at least one semiconductor layer from the liquid deposited one or more zinc oxide-precursor compositions.

### BACKGROUND OF THE INVENTION

Zinc oxide is a promising channel semiconductor in thin film transistors (“TFTs”) for fabricating low cost TFT circuits for large area displays and other low cost electronics. But to produce high-mobility TFTs, conventional fabrication processes for a zinc oxide semiconductor layer for TFTs may be costly, involving high equipment investment and complex processing techniques. Thus, there is a need addressed by embodiments of the present invention for simpler, less costly fabrication processes for a zinc oxide semiconductor layer which can result in TFTs with high field-effect mobility.

The following documents provide background information:

E. Fortunato et al., “Fully Transparent ZnO Thin-Film Transistor Produced at Room Temperature,” Adv. Mater., Vol. 17, No. 5, pp. 590-594 (Mar. 8, 2005).

T. E. Park et al., “Structural and Optical Properties of ZnO Thin Films Grown by RF Magnetron Sputtering on Si Substrates,” J. Korean Phys. Soc., Vol. 45, pp. S697-S700 (December 2004).

B. J. Norris et al., “Spin coated zinc oxide transparent transistors,” J. Phys. D: Appl. Phys., Vol. 36, pp. L105-L107 (2003).

B. Sun et al., “Solution-Processed Zinc Oxide Field-Effect Transistors Based on Self-Assembly of Colloidal Nanorods,” Nano Lett., Vol. 5, No. 12, pp. 2408-2413 (2005).

Y. Takahashi et al, “Photoconductivity of Ultrathin Zinc Oxide Films,” Jpn. J. Appl. Phys., Vol. 33, pp. 6611-6615 (1994).

D. Bao et al., “Sol-gel derived c-axis oriented ZnO thin films,” Thin Solid Films, Vol. 312, pp. 37-39 (1998).

M. Ohyama et al., “Preparation of ZnO Films with Preferential Orientation by Sol-Gel Method,” J. Cer. Soc. Jpn., Vol. 104, pp. 296-300 (1996).

S. Fujihara et al., “Crystallization behavior and origin of c-axis orientation in sol-gel-derived ZnO:Li thin films on glass substrates,” Appl. Sur. Sci., Vol. 180, pp. 341-350 (2001).

K. Nishio et al., “Preparation of highly oriented thin film exhibiting transparent conduction by the sol-gel process,” J. Mater. Sci., Vol. 31, pp. 3651-3656 (1996).

### SUMMARY OF THE DISCLOSURE

In embodiments, there is disclosed a process for fabricating at least one semiconductor layer of a thin film transistor comprising: liquid depositing one or more zinc oxide-precursor compositions and forming the at least one semiconductor layer of the thin film transistor comprising crystalline zinc oxide preferentially oriented with the c-axis perpendicular to the plane of the at least one semiconductor layer from the liquid deposited one or more zinc oxide-precursor compositions.

In further embodiments, there is disclosed a process for fabricating at least one semiconductor layer of a thin film transistor comprising:

(a) liquid depositing a zinc-oxide precursor composition to result in a deposited composition;

(b) heating the deposited composition; and

(c) cooling the heated deposited composition,

wherein the features (a), (b), and (c) are each optionally accomplished multiple times in any effective arrangement, wherein the optional multiple occurrences of the liquid depositing are each accomplished with the same or different zinc-oxide precursor composition, resulting in the at least one semiconductor layer of the thin film transistor comprising crystalline zinc oxide preferentially oriented with the c-axis perpendicular to the plane of the at least one semiconductor layer.

In additional embodiments, there is disclosed a process comprising:

fabricating a thin film transistor comprising at least one semiconductor layer, a gate electrode; a source electrode in contact with the at least one semiconductor layer; a drain electrode in contact with the at least one semiconductor layer; and a gate dielectric disposed between the at least one semiconductor layer and the gate electrode,

wherein the at least one semiconductor layer is formed by a semiconductor fabrication process comprising: liquid depositing one or more zinc oxide-precursor compositions and forming the at least one semiconductor layer of the thin film transistor comprising crystalline zinc oxide preferentially oriented with the c-axis perpendicular to the plane of the at least one semiconductor layer from the liquid deposited one or more zinc oxide-precursor compositions.

### BRIEF DESCRIPTION OF THE DRAWINGS

Other aspects of the present invention will become apparent as the following description proceeds and upon reference to the following figures which represent illustrative embodiments:

FIG. 1 represents a first embodiment of a TFT made using the present process;

FIG. 2 represents a second embodiment of a TFT made using the present process;

FIG. 3 represents a third embodiment of a TFT made using the present process;

FIG. 4 represents a fourth embodiment of a TFT made using the present process;

FIG. 5 shows the X-ray diffraction measurement results of the ZnO thin film prepared according to Example 1; and

FIG. 6 shows the X-ray diffraction measurement results of the ZnO thin film prepared according to the Comparative Example.

Unless otherwise noted, the same reference numeral in different Figures refers to the same or similar feature.

### DETAILED DESCRIPTION

In embodiments, the present process involves fabricating high mobility zinc oxide semiconductor layer(s) in TFTs by depositing a zinc oxide-precursor composition, followed by a heat treatment at a temperature (e.g., below about 550° C.), which is compatible with commonly used substrates (e.g., a Corning 7059 glass has a deformation temperature of 593° C. and can be used as the substrate for active matrix liquid crystal displays at a processing temperature below 600° C.). The resulting semiconductor layer has a preferential zinc oxide crystal orientation with c-axis perpendicular to the plane of semiconductor layer. In embodiments, the mobility of TFTs fabricated using the present process may be more than about 1 cm²/V.s., exceeding most of TFTs fabricated by other liquid deposition techniques.

In the present process, one, two, or more semiconductor layers may be fabricated. Each semiconductor layer may result from one, two, or more liquid deposition coatings of a zinc oxide-precursor composition. Whether one semiconductor layer or multiple semiconductor layers are formed depends on a number of factors including for example the zinc oxide precursor composition(s), the heating conditions, and the number of occurrences of the various process features (a), (b), and (c). In embodiments involving multiple semiconductor layers, each semiconductor layer can differ from each in for example chemical composition, crystalline orientation, and/or degree of crystallinity.

Zinc oxide thin film crystal usually has a Wurtzite structure with lattice parameters a=3.2960 and c=5.2065 Å. The orientation of the zinc oxide can be analyzed using for example x-ray diffraction (XRD) technique. For randomly oriented zinc oxide crystals, three peaks can be observed with d-spacing distance of d=2.81, 2.60, 2.48 Å for (100), (002), and (101) plane, respectively, by using Cu Kα radiation (λ1.5418 Å). The intensity ratios of these peaks in a randomly oriented zinc oxide powder sample are respectively about I₍₁₀₀₎/I₍₀₀₂₎/I₍₁₀₁₎=57/44/100 (intensities are obtained from ICDD/JCPDS card No. 36-1451 provided by The International Centre for Diffraction Data®). For randomly oriented zinc oxide crystals, the percentage of the intensity of the (002) peak relative to the sum of intensities of (100), (002), and (101) peak, I₍₁₀₀₎+I₍₀₀₂₎+I₍₁₀₁₎, I₍₀₀₂₎/[I₍₁₀₀₎+I₍₀₀₂₎+I₍₁₀₁₎]×100%, is about 22%±2%.

The crystalline zinc oxide in the semiconductor layer is preferentially oriented with the c-axis perpendicular to the plane of the semiconductor layer. In embodiments, this preferential orientation refers to the crystalline zinc oxide in the semiconductor layer having a percentage of x-ray diffraction intensity of the (002) peak relative to the sum of intensities of (100), (002), and (101) peak, I₍₀₀₂₎/[I₍₁₀₀₎+I₍₀₀₂₎+I₍₁₀₁₎]×100%, larger than about 40%, larger than about 60%, larger than about 80% (or from about 40% to about 100%, from about 60% to about 100%, from about 80% to about 100%).

The zinc oxide precursor compositions with different types of components or with the same components but different concentrations are herein considered different from each other.

In embodiments, the deposited composition (that is, resulting from the liquid depositing) may have the same components as the zinc oxide-precursor composition used for the liquid depositing and may or may not differ in concentration of the components (certain liquid deposition techniques possibly may cause some evaporation/removal of the components).

The present process comprises: (a) liquid depositing a zinc-oxide precursor composition to result in a deposited composition; (b) heating the deposited composition; and (c) cooling the heated deposited composition. The features (a), (b), and (c) are each accomplished, one, two, or more times in “any effective arrangement.” To illustrate the meaning of “any effective arrangement,” the following examples are provided of illustrative sequences:

(a)+(b)+(c);

(a)+(a)+(b)+(c);

(a)+(b)+(c)+(a)+(b)+(c);

(a)+(b)+(c)+(a)+(b)+(c)+(a)+(b)+(c);

(a)+(b)+(c)+(a)+(b)+(c)+(a)+(b)+(c)+(a)+(b)+(c);

(a)+(b)+(c)+(a)+(b)+(c)+(a)+(b)+(c)+(a)+(b)+(c)+(a)+(b)+(c);

(a)+(b)+(a)+(b)+(a)+(b)+(c);

(a)+(b)+(c)+(a)+(b)+(a)+(b)+(c);

(a)+(b)+(c)+(b)+(c);

(a)+(b)+(c)+(b)+(c)+(b)+(c);

(a)+(b)+(c)+(b)+(c)+(a)+(b)+(c).

The following discussion pertains to embodiments involving multiple occurrences of feature (a), feature (b), and/or feature (c). The zinc oxide precursor composition used in each feature (a) may be the same or different from each other. The heating conditions (e.g., heating temperature profile) in each occurrence of feature (b) may be the same or different from each other. The cooling conditions (e.g., cooling temperature profile) in each occurrence of feature (c) may be the same or different from each other.

The following describes embodiments involving the number of occurrences of particular process sequences. The number of the sequence “(a)+(b)+(c)” is for instance from 1 to 20, from 1 to 10, from 1 to 5, and particularly from 1 to 3. The number of the sequence “(a)+(b)” (that is, additional to the sequence “(a)+(b)+(c)”) is for example from 0 to 10, from 0 to 5, and particularly from 0 to 2. The number of the sequence “(b)+(c)” (that is, additional to the sequence “(a)+(b)+(c)”) is for instance from 0 to 10, from 0 to 5, and particularly from 0 to 2. The sum of the sequences “(a)+(b)+(c),” “(a)+(b),” and “(b)+(c)” is from 1 to 20, from 1 to about 10, and particularly from 1 to 6.

In embodiments, the zinc oxide precursor composition comprises starting ingredients including a zinc compound, an optional complexing agent, and a solvent.

The zinc compound is selected for example from the group consisting of zinc acetate, zinc formate, zinc oxalate, zinc nitrate, zinc propionate, zinc acetylacetonate, zinc acrylate, zinc methacrylate, zinc chloride, poly(ethylene-co-acrylic acid) zinc salt, their hydrate forms, and the like, and mixtures thereof. One or more other elements such as aluminum, indium, tin, copper, nickel, lithium, sodium, molybdenum, niobium, titanium, gallium, antimony, selenium, sulfur, boron, etc., can be incorporated by mixing compounds containing these elements with the zinc compound in the zinc oxide-precursor composition. The one or more other elements described above can also be incorporated by using zinc compounds that comprise the one or more other elements such as for example zinc sulfate, zinc sulfite, ethylenediaminetetraacetic acid zinc disodium salt, cobalt/barium/zinc octoate blends, zinc borate, zinc molybdate, zinc niobate, their hydrate forms, and the like, and mixtures thereof. The amount of such other elements in the zinc oxide-precursor composition is for instance about 0.001 mol % to about 50 mol %, from about 0.01 mol % to about 10 mol %, and particularly from 0.1 mol % to about 5 mol %, relative to zinc.

A complexing agent is optionally used which has the possible benefits of increasing the viscosity of zinc oxide precursor composition to improve thin film uniformity, and facilitating the formation of the preferential orientation of zinc oxide crystals with c-axis perpendicular to the resulting semiconductor layer. The complexing agent can be for example a carboxylic acid and an organoamine.

In embodiments, the complexing agent is an organoamine selected for example from the group consisting of ethanolamine, aminopropanol, diethanolamine, 2-methylaminoethanol, N,N-dimethylaminoethanol, methoxyethylamine, methoxypropylamine, diaminoethane, diaminopropane, diaminobutane, diaminocyclohexane, and the like, and mixtures thereof.

The solvent is selected for example from the group consisting of water, methanol, ethanol, propanol, butanol, pentanol, hexyl alcohol, heptyl alcohol, ethyleneglycol, methoxyethanol, ethoxyethanol, methoxypropanol, ethoxypropanol, methoxybutanol, dimethoxyglycol, N,N-dimethylformamide, and the like, and mixtures thereof.

The concentration of the zinc oxide precursor composition is for example from about 0.01 M to about 5 M (mole per liter), from about 0.02 M to about 2 M, and particularly from about 0.05 M to about 1 M, based on the starting ingredient zinc compound. The molar ratio of the complexing agent to zinc compound is for instance from about 0.1 to about 10, from about 0.2 to about 5, and particularly from about 0.5 to about 2.

Liquid depositing the zinc oxide precursor composition can be accomplished by any liquid deposition techniques such as for instance spin coating, blade coating, rod coating, screen printing, ink jet printing, stamping and the like.

In embodiments, the heating (that is, feature (b)) refers to a heat treatment at a temperature or several temperatures within a range of between about 100° C. and about 700° C. The heating is accomplished at a maximum temperature for example from about 200° C. to about 600° C., particularly from about 300° C. to about 550° C. The heating can be accomplished for example in an instant heating manner at a certain temperature using a pre-heated heating equipment. In embodiments, the heating can be accomplished in a gradual heating manner with a heating rate that the heating equipment can achieve, ranging from for example from about 0.5 to about 100° C. per minute starting from room temperature (about 25° C.) or starting from a temperature between about 25° C. to about 100° C. In further embodiments, the heating can also be accomplished step-wise at several temperatures, such as, for example, at about 300° C., then at about 400° C., and then at about 500° C. In embodiments, the heating can also be accomplished step-wise at several temperatures, combined with gradual heating such as, for example, at about 300° C. for about 30 min, then gradually increase to about 400° C. at a heating rate of about 10° C./min, and then at about 400° C. for about 30 min. The heating can also be accomplished for instance at a higher temperature and then at a lower temperature such as first at about 500° C. and then at about 400° C.

In embodiments, “cooling” refers to bringing the temperature of the deposited composition to a temperature below about 100° C., and particularly to about room temperature (that is, about 25° C.). The cooling can be accomplished for instance in a self-cooling manner by turning off the heating equipment or in a controlled manner at a certain cooling rate such as for example from about 0.1° C./min to about 100° C./min. In embodiments, a slow cooling such as at a cooling rate of about 0.1° C./min to about 10° C./min may be employed especially from a temperature higher than about 300° C. to reduce mechanical strain in the semiconductor layer(s) and the substrate.

The preferential orientation of the crystalline zinc oxide (with c-axis perpendicular to the semiconductor layer) and the percentage of zinc oxide crystals with c-axis perpendicular to the semiconductor layer depend for instance on the zinc oxide precursor composition(s) and heating conditions.

The zinc oxide precursor compositions and thin film fabrication procedures disclosed in afore-mentioned publications are totally incorporated herein by reference.

Illustrative zinc oxide precursor compositions are for example the following: zinc acetate/diethanolamine/isopropanol (Y. Takahashi et al, “Photoconductivity of Ultrathin Zinc Oxide Films,” Jpn. J. Appl. Phys., Vol. 33, pp. 6611-6615 (1994)), zinc acetate/lactic acid/ethanol (D. Bao et al., “Sol-gel derived c-axis oriented ZnO thin films,” Thin Solid Films, Vol. 312, pp. 37-39 (1998)), zinc acetate/ethanoamine or diethanolamine)/methoxyethanol (M. Ohyama et al., “Preparation of ZnO Films with Preferential Orientation by Sol-Gel Method,” J. Cer. Soc. Jpn., Vol. 104, pp. 296-300 (1996); S. Fujihara et al., “Crystallization behavior and origin of c-axis orientation in sol-gel-derived ZnO:Li thin films on glass substrates,” Appl. Sur. Sci., Vol. 180, pp. 341-350 (2001)), zinc acetate/ethanolamine or acetylacetonate)/ethanol (K. Nishio et al., “Preparation of highly oriented thin film exhibiting transparent conduction by the sol-gel process,” J. Mater. Sci., Vol. 31, pp. 3651-3656 (1996)), the disclosures of the publications cited for their illustrative zinc oxide precursor compositions are totally incorporated herein by reference.

Embodiments of the present process include the following illustrative materials and procedures: zinc acetate/ethanolamine/alcohol as the zinc oxide precursor composition; zinc acetate/ethanolamine/methoxyethanol as the zinc oxide precursor composition; zinc acetate/ethanolamine/methoxyethanol as the zinc oxide precursor composition and an instant heating using a pre-heated heating equipment at a temperature at about 300° C. to about 600° C.; zinc acetate/ethanolamine/methoxyethanol as the zinc oxide precursor composition and instant heating using a pre-heated heating equipment at a temperature between about 350° C. to about 550° C.

The present zinc oxide semiconductor layer(s) can be used in electronic devices such as large area displays, radio-frequency identification (RFID) tags, etc. which use thin film transistors with high field-effect mobility of for example greater that ˜10⁻¹ cm²/V.s.

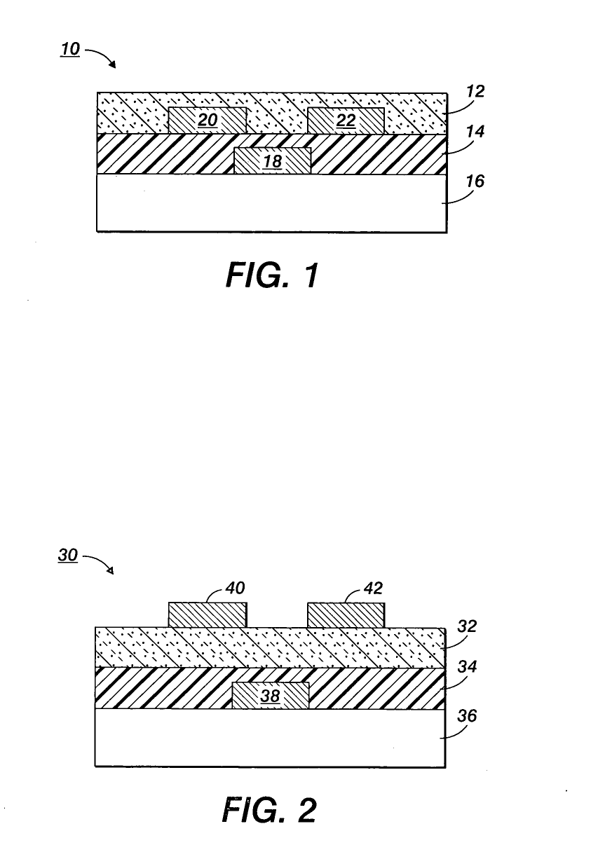

In FIG. 1, there is schematically illustrated an TFT configuration 10 comprised of a substrate 16, in contact therewith a metal contact 18 (gate electrode) and a layer of a gate dielectric layer 14 on top of which two metal contacts, source electrode 20 and drain electrode 22, are deposited. Over and between the metal contacts 20 and 22 is a zinc oxide semiconductor layer 12 as illustrated herein.

FIG. 2 schematically illustrates another TFT configuration 30 comprised of a substrate 36, a gate electrode 38, a source electrode 40 and a drain electrode 42, a gate dielectric layer 34, and a zinc oxide semiconductor layer 32.

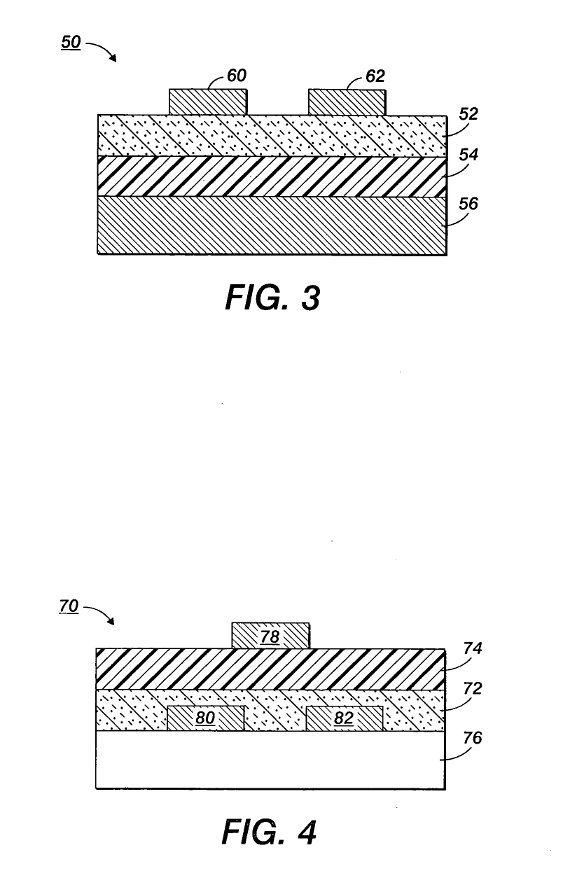

FIG. 3 schematically illustrates a further TFT configuration 50 comprised of substrate (not shown)/indium-tin oxide (ITO)/an aluminum-titanium oxide (ATO), wherein the ITO 56 is a gate electrode, and ATO 54 is a dielectric layer, and a zinc oxide semiconductor layer 52, on top of which are deposited a source electrode 60 and a drain electrode 62.

FIG. 4 schematically illustrates an additional TFT configuration 70 comprised of substrate 76, a gate electrode 78, a source electrode 80, a drain electrode 82, a zinc oxide semiconductor layer 72, and a gate dielectric layer 74.

The composition and formation of the zinc oxide semiconductor layer are described herein.

The zinc oxide semiconductor layer has a thickness ranging for example from about 10 nanometers to about 1 micrometer, particularly a thickness of from about 20 to about 200 nanometers. The TFT devices contain a semiconductor channel with a width, W and length, L. The semiconductor channel width may be, for example, from about 0.1 micrometers to about 5 millimeters, with a specific channel width being about 5 micrometers to about 1 millimeter. The semiconductor channel length may be, for example, from about 0.1 micrometer to about 1 millimeter with a more specific channel length being from about 5 micrometers to about 100 micrometers.

The substrate may be composed of any suitable materials for instance silicon, glass, aluminum, or plastics. The thickness of the substrate may be from about 10 micrometers to over 10 millimeters with a representative thickness being from about 1 to about 10 millimeters for a rigid substrate such as glass plate or silicon wafer.

The gate electrode can be a thin metal film, a conducting polymer film, a conducting film made from conducting ink or paste or the substrate itself, for example heavily doped silicon. Examples of gate electrode materials include but are not restricted to aluminum, nickel, gold, silver, copper, zinc, indium, zinc-gallium oxide, indium tin oxide, indium-antimony oxide, conducting polymers such as polystyrene sulfonate-doped poly(3,4-ethylenedioxythiophene) (PSS-PEDOT), conducting ink/paste comprised of carbon black/graphite or colloidal silver dispersion in polymer binders, such as ELECTRODAG™ available from Acheson Colloids Company. The gate electrode can be prepared by vacuum evaporation, sputtering of metals or conductive metal oxides, coating from conducting polymer solutions or conducting inks by spin coating, casting or printing. The thickness of the gate electrode ranges for example from about 10 to about 200 nanometers for metal films and in the range of about 1 to about 10 micrometers for polymer conductors. Typical materials suitable for use as source and drain electrodes include those of the gate electrode materials such as aluminum, zinc, indium, conductive metal oxides such as zinc-gallium oxide, indium tin oxide, indium-antimony oxide, conducting polymers and conducting inks. Typical thicknesses of source and drain electrodes are about, for example, from about 40 nanometers to about 1 micrometer with the more specific thickness being about 100 to about 400 nanometers.

The gate dielectric layer generally can be an inorganic material film or an organic polymer film. Illustrative examples of inorganic materials suitable as the gate dielectric layer include aluminum-titanium oxide, aluminum oxide, silicon oxide, silicon nitride, barium titanate, barium zirconium titanate and the like; illustrative examples of organic polymers for the gate dielectric layer include polyesters, polycarbonates, poly(vinyl phenol), polyimides, polystyrene, poly(methacrylate)s, poly(acrylate)s, epoxy resin and the like. The thickness of the gate dielectric layer is, for example from about 10 nanometers to about 2000 nanometers depending on the dielectric constant of the dielectric material used. An representative thickness of the gate dielectric layer is from about 100 nanometers to about 500 nanometers. The gate dielectric layer may have a conductivity that is for example less than about 10⁻¹² S/cm.

In embodiments, the gate dielectric layer, the gate electrode, the semiconductor layer, the source electrode, and the drain electrode are formed in any sequence with the gate electrode and the semiconductor layer both contacting the gate dielectric layer, and the source electrode and the drain electrode both contacting the semiconductor layer. The phrase “in any sequence” includes sequential and simultaneous formation. For example, the source electrode and the drain electrode can be formed simultaneously or sequentially.

For a n-channel TFT, the source electrode is grounded and a bias voltage of generally, for example, about 0 volt to about 80 volts is applied to the drain electrode to collect the charge carriers transported across the semiconductor channel when a voltage of generally about −20 volts to about +80 volts is applied to the gate electrode.

In embodiments, the zinc oxide semiconductor layer in a TFT device generally exhibits a field-effect mobility of greater than for example about 1 cm²/Vs (square centimeter per Volt per second), and an on/off ratio of greater than for example about 10³. On/off ratio refers to the ratio of the source-drain current when the transistor is on to the source-drain current when the transistor is off.

The invention will now be described in detail with respect to specific embodiments thereof, it being understood that these examples are intended to be illustrative only and the invention is not intended to be limited to the materials, conditions, or process parameters recited herein. All percentages and parts are by weight unless otherwise indicated.

### EXAMPLE 1

A 0.05M-0.2 M solution of zinc acetate in a mixture of ethanolamine and methoxyethanol (with Zn/amine=1 molar ratio) was first prepared by adding methoxyethanol to a mixture of zinc acetate dihydrate dihydrate (1.10 g, 5 mmol) and ethanolamine (0.32 g, 5 mmol), followed by heating at 60° C. for 1 hr to dissolve the solid.

A TFT device having the configuration of FIG. 3 was prepared as follows. A glass substrate coated with an indium-tin oxide (ITO) layer and an aluminum-tin oxide (ATO, 100 nm) top layer was first cleaned with oxygen plasma and then drop-coated with a 0.05 M zinc acetate solution, spun on a spin-coater at a speed of 1000 rpm for 2 minutes, and then heated on a hot plate at 180° C. for 30 min. It was then placed in a pre-heated oven at 400° C. for 30 min. The coating and heating procedures were repeated twice using respectively 0.1 M and 0.2 M zinc acetate solutions. Finally, an array of aluminum source-drain electrode pairs with channel length of 90 micron and channel width of 5000 micron were vacuum-evaporated on top of the ZnO layer to form ZnO TFTs.

The TFT performance was evaluated using a Keithley 4200 SCS semiconductor characterization system. The field-effect mobility in the saturated regime, μ, was calculated according to equation (1)

I_{SD}=Cᵢμ(W/2L)(V_{G}−V_{T})² (1)

where I_{SD}=drain current at the saturated regime, W and L are respectively channel width and length, Cᵢ is the capacitance per unit area of the gate dielectric layer, and V_{G} and V_{T} are respectively gate voltage and threshold voltage. The transfer and output characteristics of the devices showed that ZnO was an n-type semiconductor. Using transistors with a dimension of W=5,000 μm and L=90 μm, the following average properties were obtained: Mobility: 1.5 cm²/V.s and current on/off ratio: 10⁴.

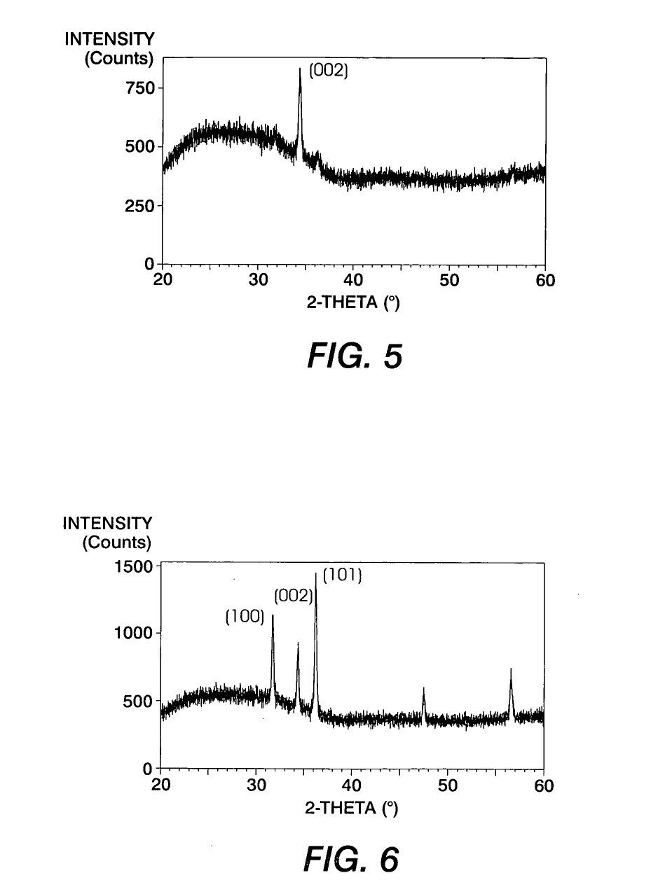

ZnO thin film on SiO₂/Si wafer was prepared similarly and subject to X-ray diffraction (XRD) measurement. FIG. 5 shows the XRD results of the ZnO thin film heated in a pre-heated oven at about 400° C. for about 30 min. The thin film was measured at room temperature on a Rigaku MiniFlex Diffractometer using Cu Kα radiation (λ1.5418 Å) with a θ-2θ scans configuration. FIG. 5 indicates that the ZnO crystals have a preferential orientation with c-axis (002) perpendicular to the substrate. The calculated I₍₀₀₂₎/[I₍₁₀₀₎+I₍₀₀₂₎+I₍₁₀₁₎]×100% is about 80%, indicating that the crystalline zinc oxide is preferentially oriented with the c-axis perpendicular to the plane of the ZnO thin film.

### COMPARATIVE EXAMPLE

ZnO TFTs were fabricated similarly as described in Example 1, except that the heating of ZnO precursor thin films at each coating was conducted in an oven by heating gradually from room temperature to about 400° C. (about 30 min) and maintained at this temperature for about 30 min. The TFT performances were as follows.

Mobility: 0.1 cm²/Vs; current on/off ratio: 10⁴.

ZnO thin film on SiO₂/Si wafer was prepared and subjected to X-ray diffraction (XRD) measurement in the manner described in Example 1 except that ZnO thin film was heated by gradual heating from room temperature to about 400° C. (about 30 min) and maintained at this temperature for about 30 min. FIG. 6 shows the XRD results of the thin film, which indicates that the ZnO crystals take a random orientation with distinct peaks representing (100), (002), and (101). The calculated I₍₀₀₂₎/[I₍₁₀₀₎+I₍₀₀₂₎+I₍₁₀₁₎]×100% is about 20%, indicating crystalline zinc oxide randomly oriented without a preferential orientation with the c-axis perpendicular to the plane of the ZnO thin film.

It will be appreciated that various of the above-disclosed and other features and functions, or alternatives thereof, may be desirably combined into many other different systems or applications. Various presently unforeseen or unanticipated alternatives, modifications, variations or improvements therein may be subsequently made by those skilled in the art which are also intended to be encompassed by the following claims. Unless specifically recited in a claim, steps or components of claims should not be implied or imported from the specification or any other claims as to any particular order, number, position, size, shape, angle, color, or material.

1. A process for fabricating at least one semiconductor layer of a thin film transistor comprising: liquid depositing one or more zinc oxide-precursor compositions and forming the at least one semiconductor layer of the thin film transistor comprising crystalline zinc oxide preferentially oriented with the c-axis perpendicular to the plane of the at least one semiconductor layer from the liquid deposited one or more zinc oxide-precursor compositions.

2. The process of claim 1, wherein the one or more zinc oxide precursor compositions comprise starting ingredients including a zinc compound, an optional complexing agent, and a solvent.

3. The process of claim 2, wherein the zinc compound is selected from the group consisting of zinc acetate, zinc formate, zinc oxalate, zinc nitrate, zinc propionate, zinc acetylacetonate, zinc acrylate, zinc methacrylate, zinc sulfite, zinc chloride, their hydrate forms, and mixtures thereof.

4. A process for fabricating at least one semiconductor layer of a thin film transistor comprising:
(a) liquid depositing a zinc-oxide precursor composition to result in a deposited composition;
(b) heating the deposited composition; and
(c) cooling the heated deposited composition,
wherein the features (a), (b), and (c) are each optionally accomplished multiple times in any effective arrangement, wherein the optional multiple occurrences of the liquid depositing are each accomplished with the same or different zinc-oxide precursor composition,
resulting in the at least one semiconductor layer of the thin film transistor comprising crystalline zinc oxide preferentially oriented with the c-axis perpendicular to the plane of the at least one semiconductor layer.

5. The process of claim 4, wherein the feature (a) is accomplished multiple times using one to five zinc-oxide precursor compositions.

6. The process of claim 4, wherein the features (a), (b), and (c) are each accomplished only once.

7. The process of claim 4, wherein the features (a), (b), and (c) are each accomplished more than once in any effective arrangement.

8. The process of claim 4, wherein the features (a), (b), and (c) are each accomplished three times in any effective arrangement.

9. The process of claim 4, wherein the heating is accomplished multiple times at different heating rates.

10. The process of claim 4, wherein the zinc oxide precursor composition comprises starting ingredients including a zinc compound, an optional complexing agent, and a solvent.

11. The process of claim 10, wherein the zinc compound is selected from the group consisting of zinc acetate, zinc formate, zinc oxalate, zinc nitrate, zinc propionate, zinc acetylacetonate, zinc acrylate, zinc methacrylate, zinc sulfite, zinc chloride, their hydrate forms, and mixtures thereof.

12. The process of claim 10, wherein the complexing agent is an organoamine selected from the group consisting of ethanolamine, aminopropanol, diethanolamine, 2-methylaminoethanol, N,N-dimethylaminoethanol, methoxyethylamine, methoxypropylamine, diaminoethane, diaminopropane, diaminobutane, diaminocyclohexane, and mixtures thereof.

13. The process of claim 10, wherein the solvent is selected from the group consisting of water, methanol, ethanol, propanol, butanol, pentanol, hexyl alcohol, heptyl alcohol, ethyleneglycol, methoxyethanol, ethoxyethanol, methoxypropanol,ethoxypropanol, methoxybutanol, dimethoxyglycol, N,N-dimethylformamide, and mixtures thereof.

14. The process of claim 4, wherein the zinc oxide precursor composition comprises starting ingredients including zinc acetate, ethanolamine, and methoxyethanol.

15. The process of claim 4, wherein the heating is accomplished at a maximum temperature from about 100 degrees C. to about 700 C degrees C.

16. The process of claim 4, wherein the heating is accomplished at a heating rate ranging from 0.5 to about 100 degrees C./minute.

17. A process comprising:
fabricating a thin film transistor comprising at least one semiconductor layer, a gate electrode; a source electrode in contact with the at least one semiconductor layer; a drain electrode in contact with the at least one semiconductor layer; and a gate dielectric disposed between the at least one semiconductor layer and the gate electrode,
wherein the at least one semiconductor layer is formed by a semiconductor fabrication process comprising: liquid depositing one or more zinc oxide-precursor compositions and forming the at least one semiconductor layer of the thin film transistor comprising crystalline zinc oxide preferentially oriented with the c-axis perpendicular to the plane of the at least one semiconductor layer from the liquid deposited one or more zinc oxide-precursor compositions.

18. The process of claim 17, wherein the thin film transistor has a field-effect mobility of greater than 0.3 cm²V⁻¹s⁻¹.

19. The process of claim 17, wherein the thin film transistor has a field-effect mobility of greater than 5 cm²V⁻¹s⁻¹.

20. The process of claim 17, wherein the thin film transistor has a field-effect mobility of greater than 10 cm²V⁻¹s⁻¹.
